(19) United States
(12) Patent Application Publication
(10) Pub. No.: US 2023/0100538 A1
(43) Pub. Date: Mar. 30, 2023

(54) DISPLAY PANEL AND DISPLAY APPARATUS

(71) Applicants: BEIJING BOE SENSOR TECHNOLOGY CO., LTD., Beijing (CN); BOE TECHNOLOGY GROUP CO., LTD., Beijing (CN)

(72) Inventors: Xuecheng HOU, Beijing (CN); Chuncheng CHE, Beijing (CN); Cheng LI, Beijing (CN)

(21) Appl. No.: 16/977,399

(22) PCT Filed: Nov. 15, 2019
(86) PCT No.: PCT/CN2019/118952

§ 371 Date: Sep. 1, 2020

(51) Int. Cl. H01L 27/146; H01L 25/18; G06V 40/13

(52) U.S. Cl. CPC H01L 27/14625; H01L 25/18; G06V 40/1318; H01L 27/3244

(57) ABSTRACT

The present disclosure relates to a display panel and a display apparatus. The display panel includes a display substrate for displaying, a sensing substrate for sensing fingerprints disposed opposite to the display substrate, the sensing substrate including a first substrate and a photosensitive device located on a side of the first substrate facing the display substrate, and a light collimating layer located between the display substrate and the photosensitive device, the light collimating layer being used to collimate light propagating toward the photosensitive device.

### CROSS REFERENCE TO RELATED APPLICATIONS

This patent application is a National Stage Entry of PCT/CN2019/118952 filed on Nov. 15, 2019, the disclosure of which is incorporated by reference herein in its entirety as part of the present application.

### BACKGROUND

Embodiments of the present disclosure relate to a field of displaying technology, in particular, to a display panel and a display apparatus.

The under-screen optical fingerprint identification technology is in line with the development trend of full-screen mobile phones. This technology enables fingerprint unlocking everywhere on the display.

### BRIEF DESCRIPTION

Embodiments of the present disclosure provide a display panel and a display apparatus.

An embodiment of the present disclosure provides a display panel. The display panel includes a display substrate for displaying, a sensing substrate for sensing fingerprints disposed opposite to the display substrate, the sensing substrate including a first substrate and a photosensitive device located on a side of the first substrate facing the display substrate, and a light collimating layer located between the display substrate and the photosensitive device, the light collimating layer being used to collimate light propagating toward the photosensitive device.

In an embodiment of the present disclosure, the photosensitive device includes an electrode layer located on the first substrate and a photosensitive layer covering the electrode layer. The electrode layer includes a first electrode and a second electrode spaced apart.

In an embodiment of the present disclosure, the photosensitive layer includes a semiconductor material.

In an embodiment of the present disclosure, the first electrode has a first main electrode and a first sub-electrode extending from the first main electrode. The second electrode has a second main electrode and a second sub-electrode extending from the second main electrode. The first sub-electrode and the second sub-electrode are alternately disposed and isolated from each other.

In an embodiment of the present disclosure, the first electrode and the second electrode are comb-shaped electrodes and form an interdigitated structure with each other.

In an embodiment of the present disclosure, the photosensitive device further includes a first insulating layer located between the electrode layer and the photosensitive layer.

In an embodiment of the present disclosure, the sensing substrate further includes a protective layer covering the photosensitive device.

In an embodiment of the present disclosure, the sensing substrate further includes a first thin film transistor located between the first substrate and the photosensitive device. A source/drain electrode of the first thin film transistor is electrically connected to one of the first electrode and the second electrode.

In an embodiment of the present disclosure, the sensing substrate further includes a light shielding part located between the first thin film transistor and the photosensitive device. An orthographic projection of the light shielding part on the first substrate overlaps with an orthographic projection of an active layer of the first thin film transistor on the first substrate.

In an embodiment of the present disclosure, the display substrate includes an OLED display substrate.

In an embodiment of the present disclosure, the display substrate includes a second substrate, a light emitting device located on a side of the second substrate away from the sensing substrate, an encapsulation layer located on the light emitting device, a polarizing layer located on the encapsulation layer, and a third substrate located on the polarizing layer.

An embodiment of the present disclosure provides a display apparatus. The display apparatus includes the display panel as described above.

Adaptive and further aspects and scope will become apparent from the description provided herein. It should be understood that various aspects of this disclosure may be implemented individually or in combination with one or more other aspects. It should also be understood that the description and specific examples herein are intended for purposes of illustration only and are not intended to limit the scope of the present disclosure.

### BRIEF DESCRIPTION OF THE DRAWINGS

The drawings described herein are for illustrative purposes only of selected embodiments and not all possible implementations, and are not intended to limit the scope of the present application.

FIG. 1 shows a schematic cross-sectional view of a display panel according to an embodiment of the present disclosure.

FIG. 2 shows a schematic cross-sectional view of a photosensitive device according to an embodiment of the present disclosure.

FIG. 3 shows a schematic cross-sectional view of a photosensitive device according to an embodiment of the present disclosure.

FIG. 4 shows a schematic view of a planar structure of an electrode layer according to an embodiment of the present disclosure.

FIG. 5 shows a schematic cross-sectional view of the sensing substrate taken along the line A-A in FIG. 4 according to an embodiment of the present disclosure.

FIG. 6 shows a schematic cross-sectional view of a display panel according to an embodiment of the present disclosure.

Corresponding reference numerals indicate corresponding parts or features throughout the several views of the drawings.

### DETAILED DESCRIPTION

As used herein and in the appended claims, the singular form of a word includes the plural, and vice versa, unless the context clearly dictates otherwise. Thus, the references “a”, “an”, and “the” are generally inclusive of the plurals of the respective terms. Similarly, the words “comprise”, “comprises”, and “comprising” are to be interpreted inclusively rather than exclusively. Likewise, the terms “include”, “including” and “or” should all be construed to be inclusive, unless such a construction is clearly prohibited from the context. The term “example” used herein, particularly when followed by a listing of terms, is merely exemplary and illustrative and should not be deemed to be exclusive or comprehensive.

Additionally, further to be noted, when the elements and the embodiments thereof of the present application are introduced, the articles “a/an”, “one”, “the” and “said” are intended to represent the existence of one or more elements. Unless otherwise specified, “a plurality of” means two or more. The expressions “comprise”, “include”, “contain” and “have” are intended as inclusive and mean that there may be other elements besides those listed. The terms such as “first” and “second” are used herein only for purposes of description and are not intended to indicate or imply relative importance and the order of formation.

The flow diagrams depicted herein are just one example. There may be many variations to this diagram or the steps (or operations) described therein without departing from the spirit of the disclosure. For instance, the steps may be performed in a differing order or steps may be added, deleted, or modified. All of these variations are considered a part of the claimed disclosure.

Exemplary embodiments will now be described more fully with reference to the accompanying drawings.

The fingerprint identification apparatus in the related art cannot realize full-screen fingerprint identification due to the limitation of manufacturing cost and the like. In addition, the photosensitive device used for fingerprint identification occupies a small area within the fingerprint identification apparatus, thereby leading to a low filling rate (ratio of the photosensitive area to the area of the display panel) and thus low sensitivity.

The embodiments of the present disclosure provide a display panel with a fingerprint identification function and a display apparatus, which can realize full-screen fingerprint identification and improve fingerprint identification sensitivity.

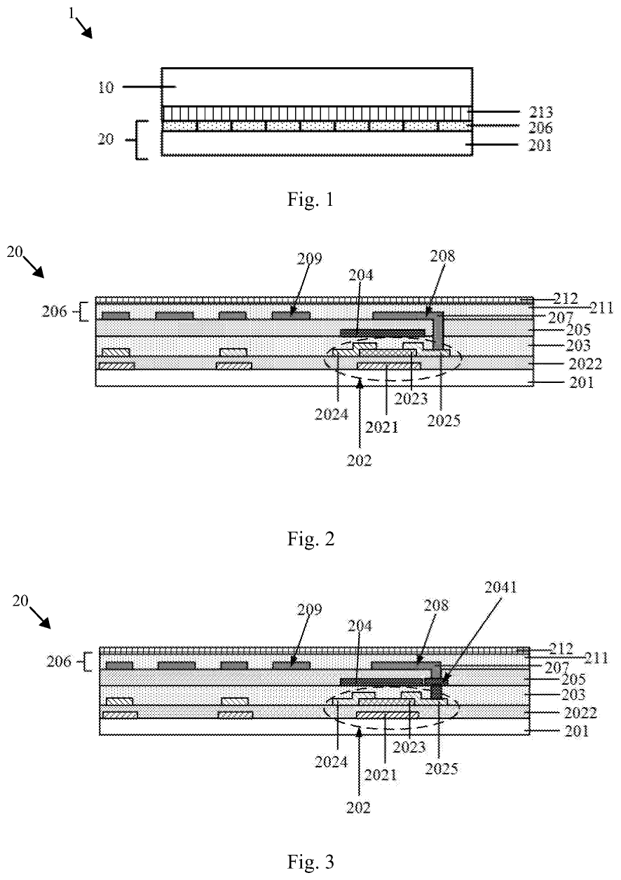

FIG. 1 shows a schematic cross-sectional view of a display panel according to an embodiment of the present disclosure. As shown in FIG. 1, the display panel 1 includes a display substrate 10 for displaying, and a sensing substrate 20 disposed opposite to the display substrate 10 for sensing fingerprints.

In an exemplary embodiment of the present disclosure, the sensing substrate 20 includes a first substrate 201 and a photosensitive device 206 on a side of the first substrate 201 facing the display substrate 10. The photosensitive device 206 is used to detect light reflected by a finger when the finger touches the display apparatus for fingerprint identification.

In an exemplary embodiment of the present disclosure, a maximum range of the dimension of the photosensitive device 206 in a direction parallel to the sensing substrate 20 is about 50-100 μm.

In an exemplary embodiment of the present disclosure, referring to FIG. 1, the display panel 1 further includes a light collimating layer 213 located between the display substrate 10 and the photosensitive device 206. When the display panel 1 is used for fingerprint identification, the light collimating layer 213 may be used to collimate the light propagating toward the photosensitive device 206, for example, so as to reduce a divergence angle of the light reflected from the valley and ridge of the finger.

In an exemplary embodiment of the present disclosure, the light collimating layer 213 may be an optical fiber layer, for example.

FIG. 2 shows a schematic cross-sectional view of a photosensitive device according to an embodiment of the present disclosure. As shown in FIG. 2, in an exemplary embodiment of the present disclosure, the photosensitive device 206 includes an electrode layer 207 located on the first substrate 201 and a photosensitive layer 211 covering the electrode layer 207. The electrode layer 207 includes a first electrode 208 and a second electrode 209 spaced apart.

As an example, one of the first electrode 208 and the second electrode 209 may include a sensing electrode, and the other may include a bias electrode, for example. The bias electrode is used to provide a bias voltage to the photosensitive layer, and the sensing electrode is used to receive electrical signals, such as electrons, from the photosensitive layer.

In an exemplary embodiment of the present disclosure, a range of the thickness of the electrode layer 207 may be about 30-50 nm, for example.

In an exemplary embodiment of the present disclosure, as an example, the photosensitive layer 211 may include a semiconductor material, for example. In an exemplary embodiment of the present disclosure, a material of the photosensitive layer 211 may include, for example, an organic material or an inorganic material. As an example, the inorganic material may include amorphous silicon, for example.

In an exemplary embodiment of the present disclosure, a range of the sensitive wavelength of the photosensitive layer 211 may be, for example, about 400-800 nm.

In an exemplary embodiment of the present disclosure, a range of the thickness of the photosensitive layer 211 may be, for example, about 450-1000 nm.

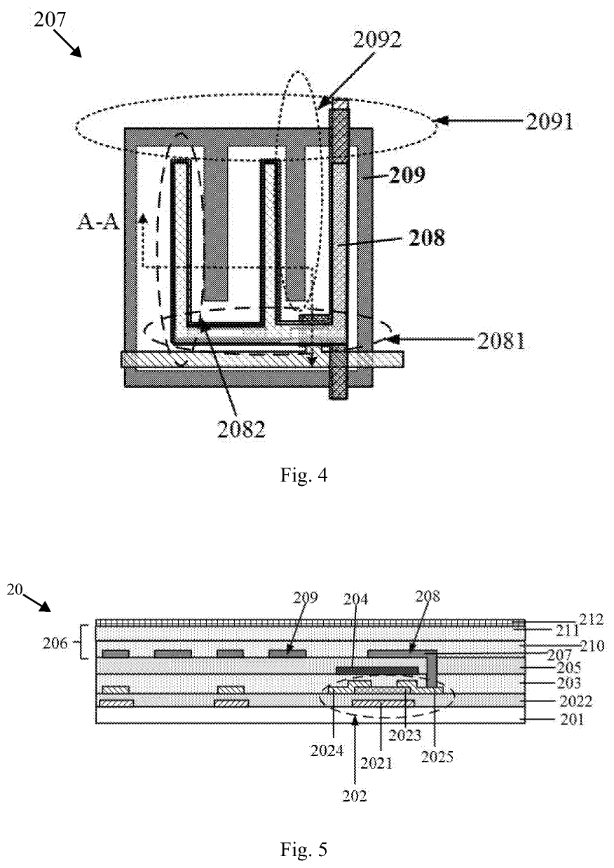

FIG. 4 shows a schematic view of a planar structure of an electrode layer according to an embodiment of the present disclosure. As shown in FIG. 4, in an exemplary embodiment of the present disclosure, the first electrode 208 has a first main electrode 2081 and a first sub-electrode 2082 extending from the first main electrode 2081. The second electrode 209 has a second main electrode 2091 and a second sub-electrode 2092 extending from the second main electrode 2091. In an exemplary embodiment of the present disclosure, the first sub-electrodes 2082 and the second sub-electrodes 2092 are alternately disposed and isolated from each other.

In an exemplary embodiment of the present disclosure, as shown in FIG. 4, the first electrode 208 and the second electrode 209 may be comb-shaped electrodes and form an interdigitated structure with each other, for example.

Referring to FIG. 2 again, in an exemplary embodiment of the present disclosure, the sensing substrate 20 further includes a first thin film transistor 202 located between the first substrate 201 and the photosensitive device 206.

In an exemplary embodiment of the present disclosure, the first thin film transistor 202 includes a gate 2021 located on the first substrate 201, a gate insulating layer 2022 covering the first substrate 201 and the gate 2021, an active layer 2023 located on the gate insulating layer 2022, and a source/drain electrode located on the active layer 2023 and the gate insulating layer 2022. In FIG. 2, for example, the source/drain electrode may include one of a source electrode 2024 and a drain electrode 2025. It should be noted that the structure provided in the same layer as the gate 2021 and the structure provided in the same layer as the source electrode 2024 and the drain electrode 2025 in FIG. 2 are other wirings.

In an exemplary embodiment of the present disclosure, the sensing substrate 20 further includes a light shielding part 204 located between the first thin film transistor 202 and the photosensitive device 206. An orthographic projection of the light shielding part 204 on the first substrate 201 overlaps with an orthographic projection of the active layer 2023 of the first thin film transistor 202 on the first substrate 201. In an embodiment of the present disclosure, the light shielding part 204 may be used to prevent the light used for displaying and the light reflected by the fingerprint and used for fingerprint identification from irradiating the active layer 2023, so as to protect switching characteristics of the first thin film transistor 202 from being affected by the above light.

In an exemplary embodiment of the present disclosure, a material of the light shielding part 204 may include metal, for example, or may be a resin material that does not transmit light.

In an exemplary embodiment of the present disclosure, the sensing substrate 20 further includes a first dielectric layer 203 located between the first thin film transistor 202 and the light shielding part 204, and a second dielectric layer 205 located between the light shielding part 204 and the photosensitive device 206.

In an exemplary embodiment of the present disclosure, one of the source electrode 2024 and the drain electrode 2025 of the first thin film transistor 202 is electrically connected to one of the first electrode 208 and the second electrode 209, and the other of the source electrode 2024 and the drain electrode 2025 is electrically connected to a signal receiving circuit (not shown), and the other of the first electrode 208 and the second electrode 209 is connected to a bias voltage circuit (not shown) as the bias electrode. For example, as shown in FIG. 2, in an exemplary embodiment of the present disclosure, the drain electrode 2025 of the first thin film transistor 202 is electrically connected to one (for example, the first electrode 208) of the first electrode 208 and the second electrode 209 through a first via (not shown) in the first dielectric layer 203 and a second via (not shown) in the second dielectric layer 205. It should be understood that in this case, the first electrode 208 serves as the sensing electrode, and the second electrode 209 serves as the bias electrode. Here, the photosensitive layer 211 converts the light incident therein into an electric signal, and the electric signal is transmitted to the first thin film transistor 202 via the first electrode 208. Then, the first thin film transistor 202 transmits the electrical signal to the signal receiving circuit to identify the fingerprint signal.

In an exemplary embodiment of the present disclosure, the first electrode 208 may be connected to the drain electrode 2025 of the first thin film transistor 202 by two methods. As an example, as shown in FIG. 2, for the first method, the material of the first electrode 208 can fill the first via in the first dielectric layer 203 and the second via in the second dielectric layer 205 to cause the first electrode 208 being directly electrically connected to the drain electrode 2025. As another example, as shown in FIG. 3, for the second method, in the case where the material of the light shielding part 205 is a conductive material, a connecting part 2041 provided in the same layer as the light shielding part 205 can fill the first via in the first dielectric layer 203 and be electrically connected to the drain electrode 2025, so that the first electrode 208 can fill the second via in the second dielectric layer 205 and be electrically connected to the drain electrode 2025 via the connection part 2041.

In an exemplary embodiment of the present disclosure, the sensing substrate 20 may further include a protective layer 212 covering the photosensitive device 206.

FIG. 5 shows a schematic cross-sectional view of the sensing substrate taken along the line A-A in FIG. 4 according to an embodiment of the present disclosure. As shown in FIG. 5, in an exemplary embodiment of the present disclosure, the photosensitive device 206 may further include a first insulating layer 210 located between the electrode layer 207 and the photosensitive layer 211. The first insulating layer 210 can reduce the dark-state leakage current of the photosensitive device 206.

In an exemplary embodiment of the present disclosure, the display substrate may include an OLED display substrate.

Next, the specific structure of the OLED display substrate 10 is described.

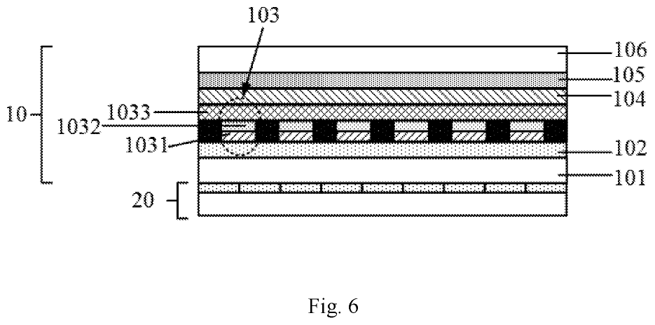

FIG. 6 shows a schematic cross-sectional view of a display panel according to an embodiment of the present disclosure. As shown in FIG. 6, in an exemplary embodiment of the present disclosure, the display substrate 10 includes a second substrate 101, a light emitting device 103 located on a side of the second substrate 101 away from the sensing substrate 20, an encapsulation layer 104 located on the light emitting device 103, a polarizing layer 105 located on the encapsulation layer 104, and a third substrate 106 located on the polarizing layer 105. In an embodiment of the present disclosure, the polarizing layer 105 may be used to avoid the influence of ambient light on the light emitting device 103, for example.

In an exemplary embodiment of the present disclosure, the light emitting device 103 may emit light for displaying, and may also emit light for fingerprint identification.

In an exemplary embodiment of the present disclosure, the light emitting device 103 may include an anode 1031, a light emitting layer 1032 located on the anode 1031, and a cathode 1033 located on the light emitting layer 1032. As an example, the cathode 1033 is a common electrode.

In an exemplary embodiment of the present disclosure, the display substrate 10 may further include a second thin film transistor 102 located between the second substrate 101 and the light emitting device 103 for driving the light emitting device 103 to emit light.

According to an embodiment of the present disclosure, a display apparatus is also provided. The display apparatus includes the display panel 1 as described above. As an example, the display apparatus may be, for example, an OLED-based display apparatus.

In the embodiment of the present disclosure, since the display panel includes a light collimating layer capable of collimating the light reaching the photosensitive device, the amount of light reaching the photosensitive device is increased, so that the sensitivity of fingerprint identification can be improved. In addition, since the photosensitive layer in the photosensitive device is provided throughout the entire display panel, full-screen fingerprint identification can be realized. Furthermore, as the photosensitive area increases, the sensitivity of fingerprint identification is further improved. Additionally, since the first electrode and the second electrode in the photosensitive device form an interdigitated structure with each other, the sensitivity of fingerprint identification is further improved.

The foregoing description of the embodiment has been provided for purpose of illustration and description. It is not intended to be exhaustive or to limit the application. Even if not specifically shown or described, individual elements or features of a particular embodiment are generally not limited to that particular embodiment, are interchangeable when under a suitable condition, can be used in a selected embodiment and may also be varied in many ways. Such variations are not to be regarded as a departure from the application, and all such modifications are included within the scope of the application.

1. A display panel comprising:
a display substrate for displaying;
a sensing substrate for sensing fingerprints disposed opposite to the display substrate, the sensing substrate comprising a first substrate and a photosensitive device located on a side of the first substrate facing the display substrate; and
a light collimating layer located between the display substrate and the photosensitive device, the light collimating layer being used to collimate light propagating toward the photosensitive device.

2. The display panel according to claim 1, wherein the photosensitive device comprises an electrode layer located on the first substrate and a photosensitive layer covering the electrode layer, and wherein the electrode layer comprises a first electrode and a second electrode spaced apart.

3. The display panel according to claim 2, wherein the photosensitive layer comprises a semiconductor material.

4. The display panel according to claim 2, wherein the first electrode has a first main electrode and a first sub-electrode extending from the first main electrode, wherein the second electrode has a second main electrode and a second sub-electrode extending from the second main electrode, and wherein the first sub-electrode and the second sub-electrode are alternately disposed and isolated from each other.

5. The display panel according to claim 4, wherein the first electrode and the second electrode are comb-shaped electrodes and form an interdigitated structure with each other.

6. The display panel according to claim 4, wherein the photosensitive device further comprises a first insulating layer located between the electrode layer and the photosensitive layer.

7. The display panel according to claim 1, wherein the sensing substrate further comprises a protective layer covering the photosensitive device.

8. The display panel according to claim 1, wherein the sensing substrate further comprises a first thin film transistor located between the first substrate and the photosensitive device, and wherein a source/drain electrode of the first thin film transistor is electrically connected to one of the first electrode and the second electrode.

9. The display panel according to claim 8, wherein the sensing substrate further comprises a light shielding part located between the first thin film transistor and the photosensitive device, and wherein an orthographic projection of the light shielding part on the first substrate overlaps with an orthographic projection of an active layer of the first thin film transistor on the first substrate.

10. The display panel according to claim 1, wherein the display substrate comprises an OLED display substrate.

11. The display panel according to claim 10, wherein the display substrate comprises:
a second substrate;
a light emitting device located on a side of the second substrate away from the sensing substrate;
an encapsulation layer located on the light emitting device;
a polarizing layer located on the encapsulation layer; and
a third substrate located on the polarizing layer.

12. A display apparatus comprising the display panel according to claim 1.

13. A display apparatus comprising the display panel according to claim 2.

14. A display apparatus comprising the display panel according to claim 3.

15. A display apparatus comprising the display panel according to claim 4.

16. A display apparatus comprising the display panel according to claim 5.

17. A display apparatus comprising the display panel according to claim 6.

18. A display apparatus comprising the display panel according to claim 7.

19. A display apparatus comprising the display panel according to claim 8.

20. A display apparatus comprising the display panel according to claim 9.
